(19) United States
(12) Patent Application Publication
(10) Pub. No.: US 2026/0111638 A1
(43) Pub. Date: Apr. 23, 2026

(54) SYSTEM FOR DESIGN RULE ENFORCEMENT, METHOD OF OPERATING SAME AND METHOD OF MANUFACTURING SAME

(71) Applicant: TAIWAN SEMICONDUCTOR MANUFACTURING COMPANY, LTD., Hsinchu (TW)

(72) Inventors: Fangyi CHANG, Hsinchu (TW); Hung-Chih OU, Hsinchu (TW)

(21) Appl. No.: 18/922,943

(22) Filed: Oct. 22, 2024

(51) Int. Cl. G06F 30/3323; G06N 3/045; G06N 3/0464; G06N 3/0475; G06N 3/092

(52) U.S. Cl. CPC G06F 30/3323; G06N 3/045; G06N 3/0464; G06N 3/0475; G06N 3/092

(57) ABSTRACT

A system (for manufacturing a semiconductor device) includes an unvalidated subject layout diagram representing the semiconductor device, the system being configured to generate the following including: a feature extractor module configured to extract subject features that at least partially comprise the unvalidated subject layout diagram; and a design rule (DR) enforcement module including a DR checker (DRC) module and layout diagram modifier (LDM) module, the DRC module being configured to check the subject features for compliance with corresponding design rules in a set thereof and to identify which of the design rules are being violated and corresponding DR-violating subject features, and the LDM module being configured to attempt reducing the DR violations by modifying the DR-violating subject features resulting in a validated subject layout diagram; the DRC module being based on a first neural network; and the LDM module being based on a second neural network.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1A is a block diagram of a design rule enforcement module, in accordance with some embodiments.

FIG. 1B is a block diagram of a triplet-based organization of a layout diagram, in accordance with some embodiments.

FIG. 1C is a block diagram of featurizing a layout diagram, in accordance with some embodiments.

FIG. 1D is a layout diagram, in accordance with some embodiments.

FIGS. 1E-1F are corresponding block diagrams of a design rule enforcement module, in accordance with some embodiments.

FIGS. 2A-2C are corresponding block diagrams of a training-data developer module, in accordance with some embodiments.

FIG. 3 is a flow diagram, in accordance with some embodiments.

FIG. 4 is a flowchart a method, in accordance with some embodiments.

FIG. 5 is a block diagram of an electronic design automation (EDA) system in accordance with some embodiments.

FIG. 6 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a system for manufacturing a semiconductor device includes a sub-system to generate the following including: a feature extractor module configured to extract subject features that at least partially comprise the unvalidated subject layout diagram; and a design rule (DR) enforcement module including a DR checker (DRC) module and layout diagram modifier (LDM) module. The DRC module is configured to check the subject features for compliance with corresponding design rules in a set thereof and to identify which of the design rules are being violated and corresponding DR-violating subject features. The LDM module is configured to attempt reducing the DR violations by modifying the DR-violating subject features resulting in a validated subject layout diagram. The DRC module is based on a first neural network, e.g., a convolutional neural network (CNN). The LDM module is based on a second neural network, e.g., a reinforcement learning (RL) network. According to another approach, a substantial portion of modifications to DR-violating features are done manually by a designer. As layout diagrams grow ever more complex, the number of modifications being made to DR-violating features has increased to a degree that solely manual adjustment substantially slows down the design process, i.e., manual modifications have became a bottleneck. At least some embodiments reduce the number of manual modifications by using the LDM module to perform the modifications, thereby reducing the bottleneck.

In some embodiments, a system for manufacturing a semiconductor device includes a sub-system to generate the following including a training data-developer (TDD) module that includes an empirical feature extractor module and a feature synthesizer module. The empirical feature extractor module is configured to extract empirical training features that at least partially comprise one or more corresponding empirical training layout diagrams and that are in design rule (DR) compliance with corresponding design rules. The feature synthesizer module is based on a first neural network, e.g., a generative-adversarial network (GAN), and is configured to generate first synthetic training features useable in one or more corresponding training layout diagrams and that are in compliance with corresponding design rules or second synthetic training features useable in one or more corresponding training layout diagrams and that are in violation of corresponding design rules.

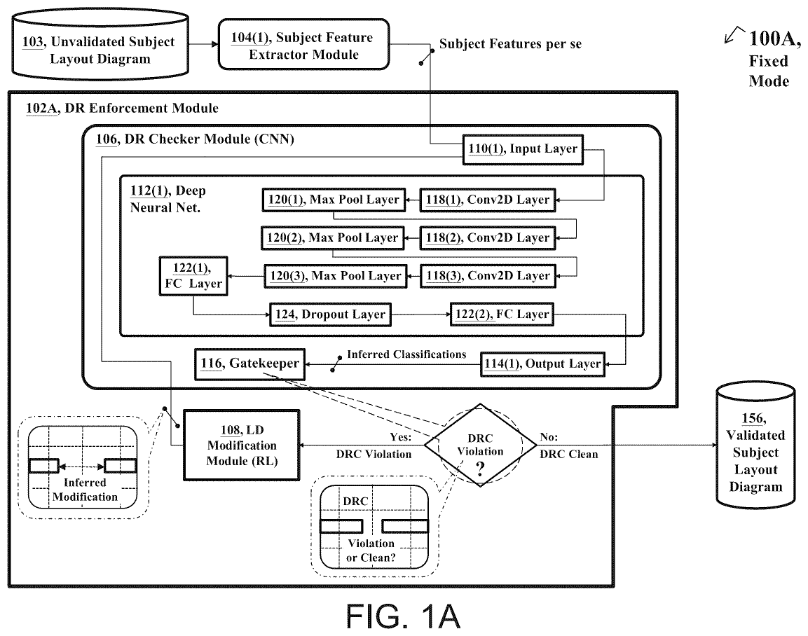

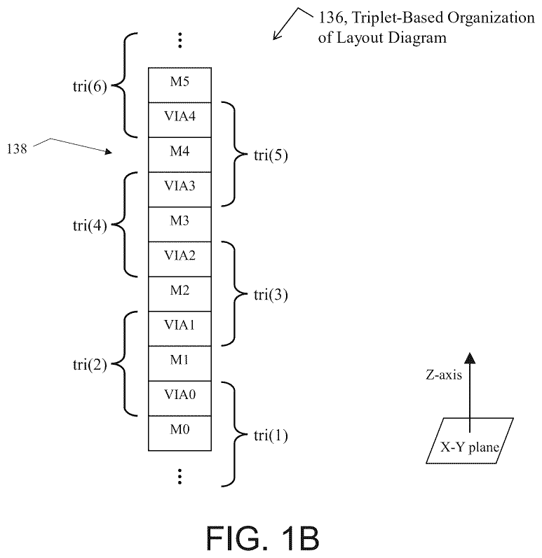

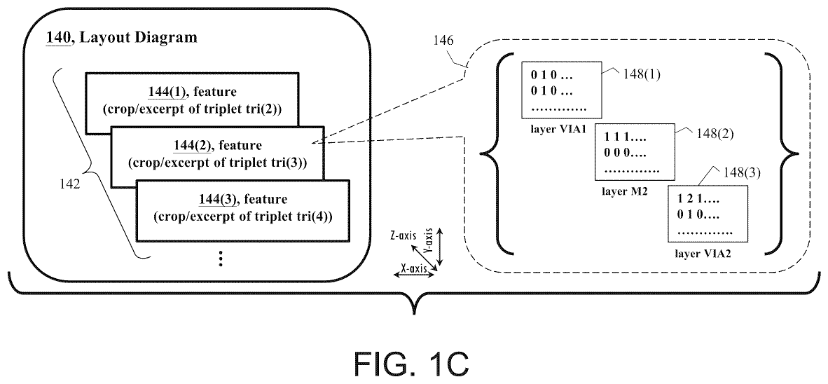

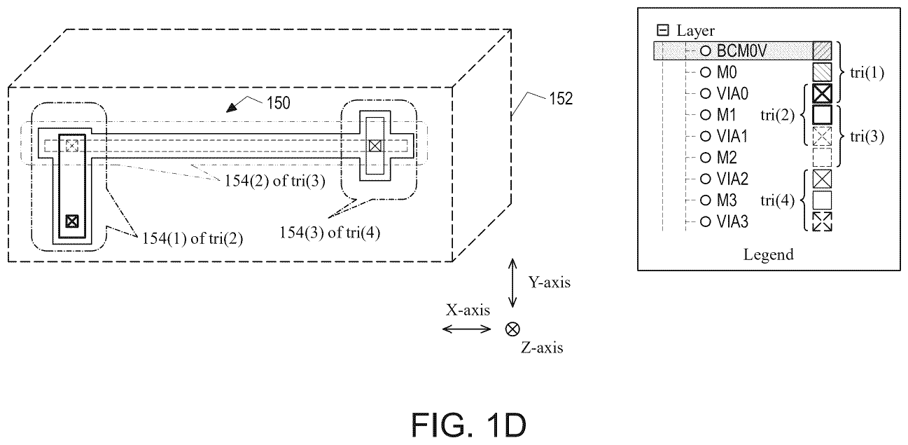

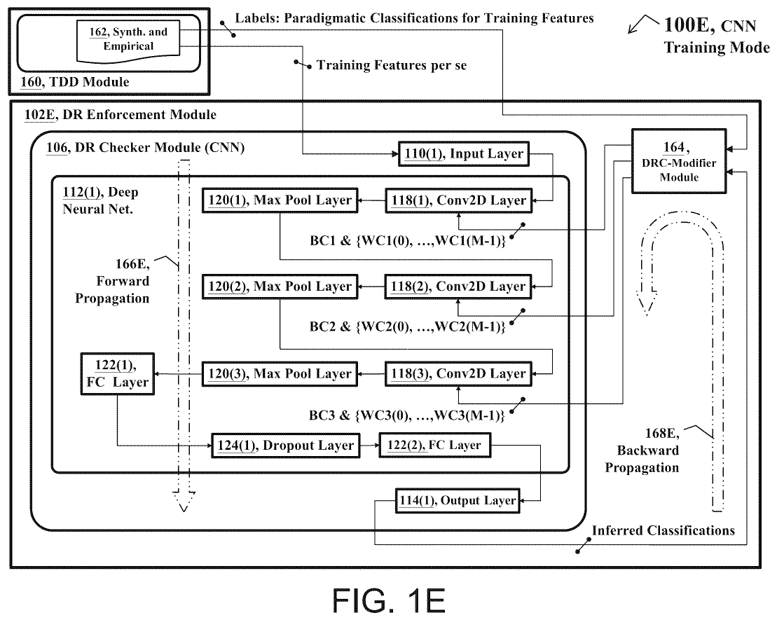

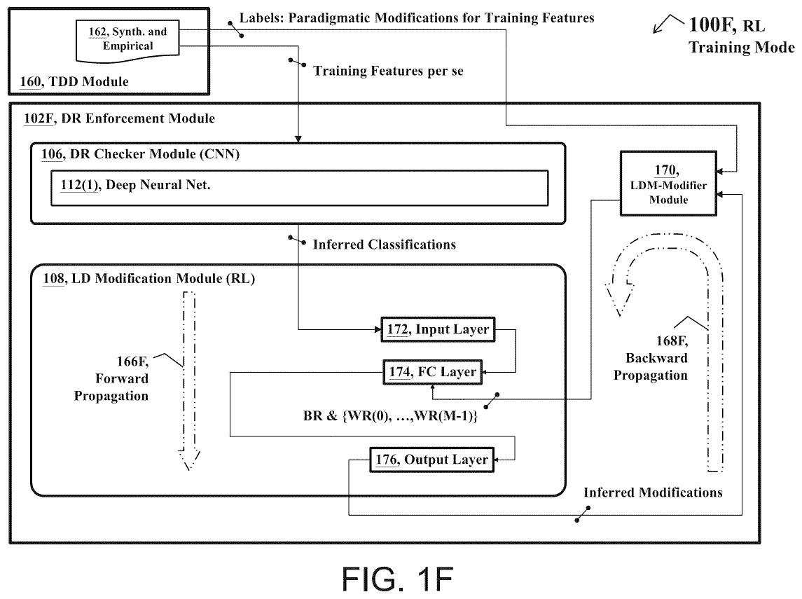

FIG. 1A is a block diagram of a system 100A, in accordance with some embodiments.

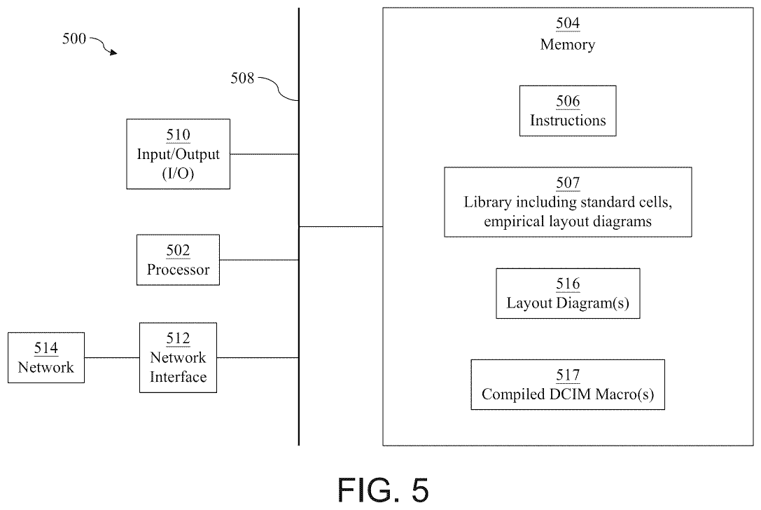

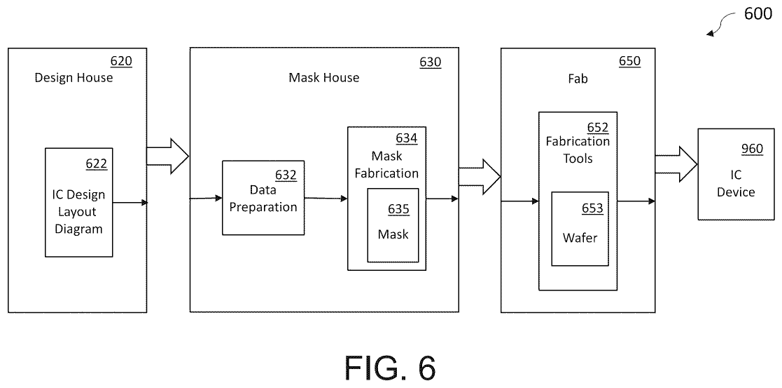

System 100A is comprised of at least one processor, at least one non-transitory computer-readable medium (see FIG. 5) that stores computer-executable code/instructions, and an unvalidated subject layout diagram 103 (discussed below) representing the semiconductor device where unvalidated subject layout diagram 103 is stored on a non-transitory computer-readable medium. The non-transitory computer-readable medium, the computer-executable code and the at least one processor are configured to cause the system to generate at least DRE module 102A and subject feature extractor module 104(1). In some embodiments, system 100A is implemented using electronic design automation (EDA) system 600 of FIG. 5 (discussed below), or the like.

System 100A includes a design rule enforcement (DRE) module 102A and a subject feature extractor module 104(1). DRE module 102A is configured to receive subject features from subject feature extractor module 104(1) and apply design rule enforcement to the subject features. A context for understanding design rule enforcement includes the following. A theoretical layout diagram that represents a semiconductor-based device, e.g., an integrated circuit (IC)), assumes ideal manufacturing capabilities, i.e., unrealistic, manufacturing capabilities. To be profitable, fabrication based on the theoretical layout diagram should achieve a high yield of operational ICs, and the resultant operational ICs should also exhibit a low failure rate, i.e., exhibit high reliability. To achieve high yield and low failure rate, the theoretical design should be adjusted to compensate for limitations of, and variability associated with, semiconductor processes and photolithographic processes that comprise the fabrication of the ICs. That is, the theoretical layout diagram should be adjusted for the corresponding semiconductor process node used to fabricate the corresponding ICs.

To facilitate adjusting a theoretical layout diagram for a given semiconductor process node, an IC manufacturer provides a designer with a set of design rules that compensate for the limitations of, and variability associated with, the given semiconductor process node. As such, design rules are a set of rules/requirements provided by semiconductor manufacturers that enable the designer to verify the manufacturability of the theoretical layout diagram and modify the same accordingly resulting in a validated layout diagram. A design rule set specifies geometric and/or connectivity restrictions to ensure sufficient margins to account for variability in semiconductor manufacturing processes. Compliance of the validated layout diagram with the design rules achieves high yield and low failure rate amongst the resulting ICs.

Design rules prescribe limitations or restrictions on relationships that can be specified in the adjusted layout diagrams, e.g., geometric limitations on the shapes of structures, geometric limitations regarding spacing between structures (e.g., adjacent or proximal structures), electrical connectivity relationships between structures, thermal behavior of structures, electromigration behavior of structures, or the like. A set/library of design rules are specific to a particular semiconductor manufacturing process node. Adjusting the theoretical layout diagram in view of the design rules is an iterative process (discussed below).

As DRE module 102A is configured to apply and enforce design rules, DRE module 102A is further configured to as follows including: apply design rules to the subject features; determine which subject features violate corresponding design rules; and modify the subject features accordingly, i.e., modify the subject layout diagram accordingly. The applying, determining and modifying are performed recursively until the subject features are in corresponding design rule (DR) compliances, i.e., until the modified subject layout diagram is in DR compliance. When the modified subject layout diagram comes into DR compliance, the unvalidated subject layout diagram has been transformed into a validated version of the subject layout diagram.

In FIG. 1A, DRE module 102A includes a DR checker (DRC) module 106 and a layout diagram modifier (LDM) module 108. DRC module 106 is a neural network. FIGS. 1A and 1E assume that DRC module 106 is a type of neural network referred to as a convolutional neural network (CNN). In some embodiments, DRC module 106 is a type of neural network other than a CNN. LDM module 108 is a neural network. FIGS. 1A and 1F assume that LDM module 108 is a type of neural network referred to as a reinforcement learning (RL) network. In some embodiments, LDM module 108 is a type of neural network other than an RL network.

Each layer in a neural network includes a set of nodes. For simplicity of illustration, the nodes of the layers of the CNN that comprises DRC module 106 and the nodes of the layers of the RL network that comprise LDM module 108 are not shown. Each set of nodes has a corresponding set of weights and one or more biases (see FIG. 1E). In some embodiments, one or more neural network layers have no corresponding biases that that each of the corresponding biases equal zero. In some embodiments, the nodes of a hidden layer are referred to as neurons.

As each is a neural network, each of DRC module 106 and LDM module 108 learns adaptively during corresponding training modes of operation. Adaptive learning by a neural network includes adaptively, and iteratively, adjusting weights and/or biases of one or more nodes/neurons in corresponding layers of the neural network. When not in a training mode, each of DRC module 106 and LDM module 108 is described as being in a corresponding fixed mode of operation.

Here, the adjective “fixed’ used to describe “mode” is intended to connote that each of DRC module 106 and LDM module 108 is assumed to be in a fixed mode of operation. Regarding system 100A and DRE module 102A, the suffix “A” correspondingly in the reference numbers indicates that FIG. 1A is showing the fixed mode of operation. A training mode of DRC module 106 is discussed below in the context of FIG. 1E. A training mode of LDM module 108 is discussed below in the context of FIG. 1F.

DRC module 106 includes: an input layer 110(1); a deep neural network 112(1); an output layer 114(1); and a gatekeeper 116. Deep neural network 112(1) includes hidden layers including: two-dimensional (2D) convolutional (Conv2D) layers 118(1)-118(3); pooling layers 120(1)-120(3); fully connected (FC) layers 122(1)-12(2); and a dropout layer 124(1). Layers of LDM module 108 are not shown in FIG. 1A, but see FIG. 1F.

In FIG. 1A, each of Conv2D layers 118(1)-118(3) is assumed to have a kernel size of 3×3. In some embodiments, one or more of Conv2D layers 118(1)-118(3) correspondingly has a kernel size different than 3×3. In FIG. 1A, each of Conv2D layers 118(1)-118(3) is assumed to have a step size of one. In some embodiments, one or more of Conv2D layers 118(1)-118(3) correspondingly has a step size different than one. In FIG. 1A, each of Conv2D layers 118(1)-118(3) is assumed to use zero padding. In some embodiments, one or more of Conv2D layers 118(1)-118(3) correspondingly uses non-zero padding.

In FIG. 1A, it is assumed that each of Conv2D layers 118(1)-118(3) has a rectified linear unit (ReLU) function as an activation function. In some embodiments, one or more of Conv2D layers 118(1)-118(3) has a corresponding activation function that is different than the ReLU function.

In FIG. 1A, output layer 114(1) is assumed to have a softmax function as an activation function. In some embodiments, output layer 114(1) has an activation function that is different than the softmax function.

In FIG. 1A, pooling layers 120(1)-120(3) are assumed to be max pooling layers. In some embodiments, one or more of pooling layers 120(1)-120(3) correspondingly are different types of pooling layers than max pooling layers. In some embodiments, deep neural network 112(1) includes a different number of pooling layers than is shown in FIG. 1A. In some embodiments, deep neural network 112(1) includes a different number of Conv2D layers than is shown in FIG. 1A.

Dropout layer 124(1) is included as a regularization technique to prevent overfitting. During the training mode of DRC module 106, a fraction (or subset) of the weights of dropout layer 124(1) are randomly set to zero at each update iteration. This helps DRC module 106 learn more robust features that are not reliant on any particular set of neurons, thereby improving generalization capabilities.

Regarding the training mode of operation of DRC module 106, during each forward propagation 166E, each neuron (excluding the output neurons) has a probability (p) (referred to as the dropout rate) of being “dropped out,” meaning its output is set to zero. The neurons that are dropped out do not contribute to the forward pass nor do they participate in backward propagation 168E. The remaining neurons are scaled up by a factor of 1/(1−p) to maintain the expected sum of inputs. Regarding the fixed mode of operation of DRC module 106, during inference, none of the weights of dropout layer 124(1) are set to zero, i.e., none of the nodes/neurons of dropout layer 124(1) are turned off, and all neurons contribute to forward propagation 166E. However, to maintain the output at the same scale as during the training mode, the weights are not scaled.

Subject feature extractor module 104(1) is configured to extract subject features (discussed below) from unvalidated subject layout diagram 103. A context for understanding subject features extracted by extractor module 104(1) includes the following. In general, a layout diagram represents a semiconductor device. Shapes (or patterns) in the layout diagram represent corresponding components in the semiconductor device. The layout diagram per se is a top view. Shapes in the layout diagram are two-dimensional relative to, e.g., the X-axis and the Y-axis, whereas the semiconductor device being represented is three-dimensional. Typically, relative to the Z-axis, the semiconductor device is organized as a stack of layers in which are located corresponding structures, i.e., to which belong corresponding structures. Accordingly, each shape in the layout diagram represents, more particularly, a component in a corresponding layer of the corresponding semiconductor device. Typically, the layout diagram represents relative depth, i.e., positions along the Z-axis, of shapes and thus layers by superimposing a second shape in a second layer on a first shape in a first layer so that the second shape at least partially overlaps the first shape. Consider similarly sized contact structures which are stacked in a layout diagram along the Z-axis, e.g., via-to-drain/source (VD) contact structures, via structures in a corresponding interconnection layer (e.g., VIA_1st contact structures in a first interconnection layer, or the like); in some embodiments, the stacking order along the Z-axis of the similarly sized contact structures shown in the layout diagram is reversed relative to the Z-axis stacking order of the corresponding contact structures in the manufactured semiconductor device which the layout diagram represents, the reversal being done in the layout diagram for simplicity of illustration. For simplicity of discussion, i.e., as a discussion-expedient, some elements in a layout diagram are referred to as if they are counterpart structures in a corresponding semiconductor device rather than shapes/patterns per se, e.g., conductive shapes/patterns are referred to as conductive segments, via shapes/patterns are referred to as via structures, or the like.

In some embodiments, unvalidated subject layout diagram 103 is represented as a set of images, e.g., raster/bitmap images, vector images, or the like. In some embodiments, unvalidated subject layout diagram 103 is represented in Graphic Design System (GDSII) format, which is a binary file format that represents planar geometric shapes, text labels, and related layout information in a hierarchical manner. In some embodiments, unvalidated subject layout diagram 103 is represented in a format other than image format or GDSII format.

FIG. 1A assumes that subject feature extractor module 104(1) is configured to use a triplett-based representation (see FIG. 1B) of a layout diagram. Furthermore, subject feature extractor module 104(1): represents each subject feature of unvalidated subject layout diagram 103 as an excerpt (see FIG. 1C) of a corresponding one of the triplets. In some embodiments, an excerpt of a triplet is referred to as a crop of the triplet.

FIG. 1B is a block diagram of a triplet-based organization 136 of a layout diagram 138, in accordance with some embodiments.

Triplet-based organization 136 is a simplistic organization of layout diagram 138. Unvalidated subject layout diagram 103 is an example of a layout diagram 138 that is organizable according to triplet-based organization 136.

In FIG. 1B, layout diagram 138 includes: metallization layers, of which metallization layers M0-M5 are shown; and interconnection layers, of which interconnection layers VIA0-VIA4 are shown.

In FIG. 1B, of the triplets included in layout diagram 138, triplets tri(1)-tri(6) are shown. In general, each triplet includes three layers stacked upon each other. Most triplets include a metallization layer, an underlying interconnection layer and an overlying interconnection layer.

Triplet tri(2) includes layer M1 and interconnection layers VIA0 and VIA1. Triplet tri(3) includes layer M2 and interconnection layers VIA1 and VIA2. Triplet tri(4) includes layer M3 and interconnection layers VIA2 and VIA3. Triplet tri(5) includes layer M4 and interconnection layers VIA3 and VIA4. Triplet tri(6) includes layer M5 and interconnection layers VIA4 and VIA5 (the latter not shown). Triplet tri(1) includes layer M0, interconnection layer VIA0, and the layer which underlies layer M0. In some embodiments, the layer which underlies layer M0 is the transistor layer (not shown) or a sub-layer therein (not shown). In some embodiments, transistor components are formed in the transistor layer.

In some embodiments, depending upon the numbering convention of the corresponding process node by which such a semiconductor device is fabricated, the first (1st) layer of metallization M_1st is either metallization layer zero, M0, or metallization layer one, M1, and correspondingly the first layer of interconnection V_1st is either VIA0 or VIA1. In FIG. 1B, the M_1st layer is assumed to be M0 and the V_1st layer is assumed to be VIA0.

FIG. 1C is a block diagram of a layout diagram 140, in accordance with some embodiments.

In FIG. 1C, layout diagram 140 is represented as a set 142 of features of which features 144(1)-144(3) are shown in FIG. 1C for simplicity of illustration. That is, layout diagram 140 is represented as a set 142 of crops/excerpts of which crops/excerpts 144(1)-144(3) are shown in FIG. 1C. Layout diagram 140 is an example of unvalidated subject layout diagram 103.

In FIG. 1C, each of features 144(1)-144(3), i.e., each of crops/excerpts 144(1)-144(3), are represented as a set of three corresponding numerical matrices of which set 146 of numerical matrices 148(1)-148(3) is shown in FIG. 1C for simplicity of illustration. Subject feature extractor module 104(1) is configured to convert an image representation of layout diagram 140, e.g., a red-blue-green (RGB) bitmap representation of layout diagram 140, into a numerical matrix format that represents each layer of layout diagram 140 as a corresponding layer-matrix.

In some embodiments, each layer of layout diagram 140 is represented as a bitmap of pixels. In each layer, a pixel at location loc(i,j) in the layer is represented as a single digit entry p(i,j) in the layer-matrix, where each of i and j is a corresponding non-negative integer.

In some embodiments, each pixel p(i,j) has a value of 0, 1 or 2. Where pixel p(i,j) represents a portion of a conductive segment in a corresponding metallization layer, p(i,j)=1. Where pixel p(i,j) represents a portion of a via structure in a corresponding interconnection layer, p(i,j)=2. Where pixel p(i,j) represents neither a portion of a via structure in a corresponding interconnection layer nor a portion of a via structure in a corresponding interconnection layer, p(i,j)=0.

In some embodiments, a crop is shaped as a rectangle in the X-Y plane. In some embodiments, the side of the rectangle parallel to the X-axis has a size Sx in a range in nanometers (nm) as follows: (≈100 nm)≤Sx≤(≈200 nm). In some embodiments, the side of the rectangle parallel to the Y-axis has a size Sy in a range in nanometers (nm) as follows: (≈100 nm)≤Sy≤(≈200 nm). In some embodiments, representing the features of layout diagram 140 as a set of instances of crop 144 is described as applying a technique of mini-batching to layout diagram 140.

From a vantage point of looking down the Z-axis onto the X-Y place, features 144(1)-144(3) are aligned relative to each of the X-axis and the Y-axis and are stacked on each other relative to the Z-axis. Together, features 144(1)-144(3) comprise a rectangular parallelepiped (152 FIG. 1D).

FIG. 1D is a layout diagram 150, in accordance with some embodiments.

Layout diagram 150 corresponds to features 144(1)-144(3) of FIG. 1C, i.e., corresponds to crops/excerpts 144(1)-144(3) of FIG. 1C. Rectangular parallelepiped 152 is superimposed on layout diagram 150.

Recalling that each of features 144(1)-144(3), i.e., each of crops/excerpts 144(1)-144(3), is represented by a corresponding set of three corresponding numerical matrices (see 148(1)-148(3) of FIG. 1C), layout diagram 150 represents pixels in features 144(1)-144(3) that have the value p(i,j)=1 or p(i,j)=2.

In FIG. 1D, region 154(1) of layout diagram 150 corresponds to triplet tri(2) (see FIG. 1B). Region 154(2) of layout diagram 150 corresponds to triplet tri(3) (see FIG. 1B). Region 154(3) of layout diagram 150 corresponds to triplet tri(4) (see FIG. 1B).

Returning the discussion to FIG. 1A, in some embodiments, there are various types of attributes appended to corresponding features including, e.g., metal-segment types that describe conductive segments in corresponding metallization layers, via attributes that describe via structures in corresponding interconnection layers, or the like.

Examples of metal-segment attributes include: a number of the metallization layer within unvalidated subject layout diagram 103 in which a given conductive segment exists; a length along the long axis of the given conductive segment; and a location of the given conductive segment in the metallization layer in which the given conductive segment exists; or the like.

In some embodiments, a width along the short axis of the given conductive segment is not an attribute of a subject feature because, in general, width along the short axis of conductive segments in the given layer is made uniform for all conductive segments in the given layer and is minimized for purposes of enhancing routability within the given layer. The width along the short axis of all conductive segments in the given layer, in effect, is a fixed parameter corresponding to the given layer. In some embodiments, however, a width along the short axis of the given conductive segment is used as an attribute of a feature.

Examples of via attributes include: a number of the interconnection layer within unvalidated subject layout diagram 103 in which a given via structure exists; a length along the long axis of the given via structure; and a location of the given via structure in the interconnection layer in which the given via structure exists; or the like.

DRC module 106 is configured to infer whether the subject features comply with or violate corresponding design rules. That is, DRC module 106 is configured to classy the subject features as being in corresponding DR compliance or DR violation, resulting in inferred classifications that are output by output layer 114(1).

Gatekeeper 116 is configured to receive the inferred classification from output layer 114(1) and determine which represent DR violations. Gatekeeper 116 is further configured to provide the features that are in DR violation to LDM module 108.

LDM module 108 is configured to attempt to reduce the DR violations by modifying the DR-violating subject features received from gatekeeper 116 to be in DR compliance with corresponding design rules. LDM module 108 provides the modified features to input layer 110(1). DRC module 106 iterates the design rule check for the modified features received from LDM module 108. In some embodiments, input layer 110(1) is described as being coupled to LDM module 108 in a feedback loop. DR enforcement module 102A iterates the processing by DRC module 106 and LDM module 108 until none of the inferred classifications provided by output layer 114(1) are in DR violation, i.e., until all of the features are in DR compliance. When none of the inferred classifications provided by output layer 114(1) are in DR violation, DRE module 102A outputs the modified subject layout diagram as the validated version of the subject layout diagram.

FIG. 1E is a block diagram of a system 100E, in accordance with some embodiments.

System 100E and DRE module 102E included therein correspond to system 100A and DRE module 102A of FIG. 1A. Whereas FIG. 1A assumes a fixed mode of operation for DRE module 102A, FIG. 1E assumes a context of DRE module 102E being in a training mode of operation, and more particularly DRC module 106 being in a training mode of operation. In some embodiments, the training mode of DRC module 106 is described as supervised training. The training mode of DRC module 106 is mutually exclusive to the training mode of LDM module 108. Accordingly, FIG. 1E assumes that LDM module 108 (not shown in FIG. 1E but see FIG. 1A) is in a fixed mode of operation.

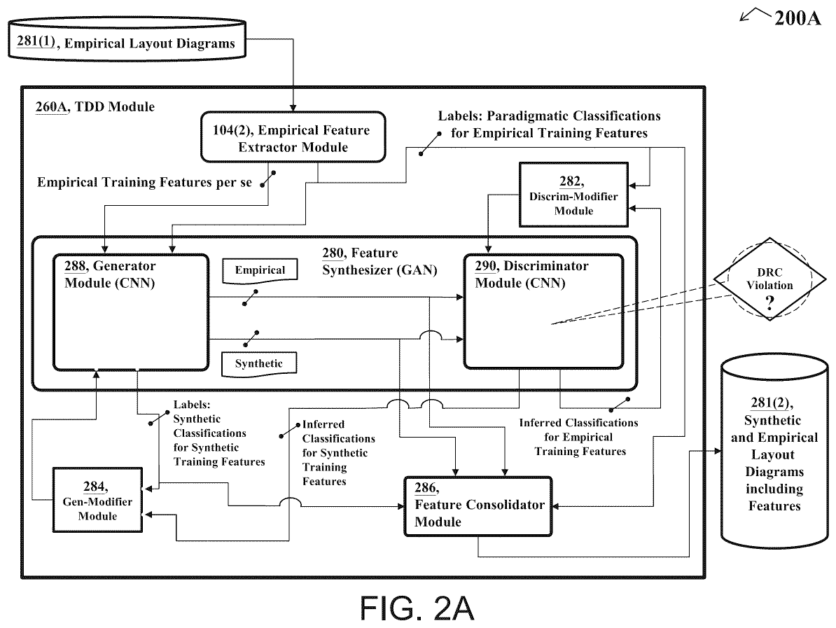

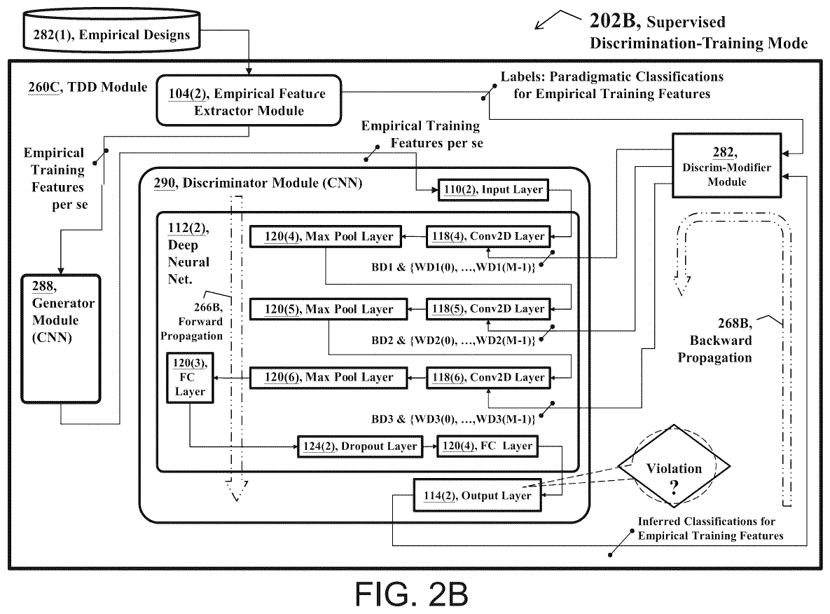

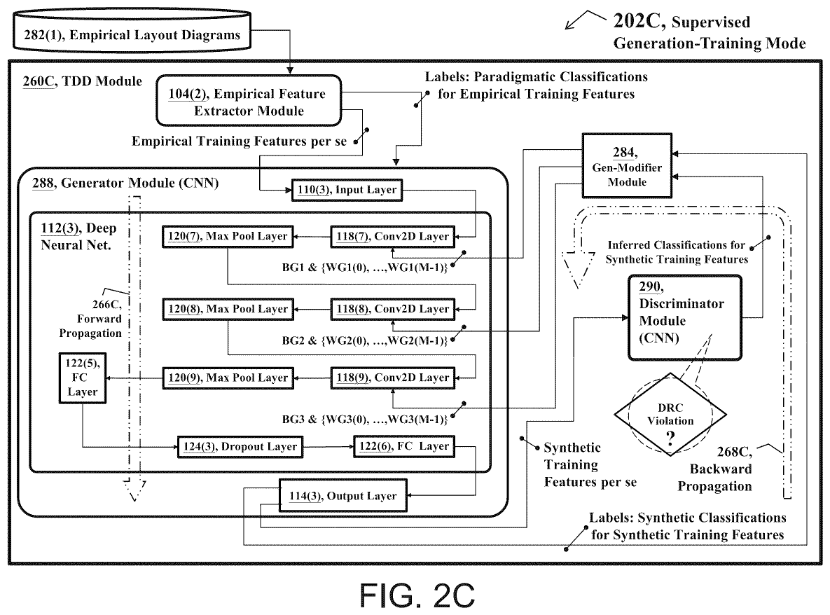

In FIG. 1E, DRE module 102C receives training features and corresponding labels, i.e., paradigmatic classifications corresponding to the training features, from a training-data developer (TDD) module 160 (see FIG. 2A). TDD module 160 develops a library 162 of features to include not only empirical features but also synthetic features. The training features and corresponding labels received by DRC module 106 are obtained from features library 162 by TDD module 160.

In FIG. 1E, input layer 110(1), deep neural net 112(1) and output layer 114(1) of DRC module 106 operate on the training features similarly to how the same operates on subject features in FIG. 1A. However, in FIG. 1E, the classifications output by output layer 114(1) are not provided to LDM module 108 (FIG. 1A). Instead, the classifications output by output layer 114(1) are provided to a DRC-modifier module 164.

In addition to receiving the inferred classifications from output layer 114(1), DRC-modifier module 164 receives the paradigmatic classifications from TDD module 160 which correspond to the training features. DRC-modifier module 164 adjusts one or more weights or one or more biases correspondingly of Conv2D layers 118(1)-118(3) by applying a recursive type of gradient descent based on differences between the paradigmatic classifications and corresponding ones of the inferred classifications. Propagation of the features from input layer 110(1) through deep neural net 112(1) to output layer 114(1) is referred to as forward propagation 166E.

DRC-modifier module 164 adjusts weights WC1(0), . . . , WC1(M−1) and a bias value BC1 and provides the same to Conv2D layer 118(1), where M is a positive integer. DRC-modifier module 164 adjusts weights WC2(0), . . . , WC2(M−1) and a bias value BC2 and provides the same to Conv2D layer 118(2). DRC-modifier module 164 adjusts weights WC3(0), . . . , WC3(M−1) and a bias value BC3 and provides the same to Conv2D layer 118(2). FIG. 1E assumes that each of Conv2D layers 118(1)-118(3) has M nodes/neurons. In some embodiments, one or more of Conv2D layers 118(1)-118(3) has different numbers of nodes/neurons.

In some embodiments, DRC-modifier module 164 does as follows including: determines the differences according to a categorical cross-entropy loss between the paradigmatic classifications and the corresponding ones of the inferred classifications; and uses Adaptive Moment Estimation (Adam) as the recursive type of gradient descent.

FIG. 1F is a block diagram of a system 100F, in accordance with some embodiments.

System 100F and DRE module 102F included therein correspond to system 100A and DRE module 102A of FIG. 1A. Whereas FIG. 1A assumes a fixed mode of operation for DRE module 102A, FIG. 1F assumes a context of DRE module 102F being in a training mode of operation, and more particularly LDM module 108 being in a training mode of operation. In some embodiments, the training mode of LDM module 108 is described as supervised training. The training mode of LDM module 108 is mutually exclusive to the training mode of DRC module 106. Accordingly, FIG. 1F assumes that DRC module 106 is in a fixed mode of operation.

Again, LDM module 108 is assumed to be a type of neural network referred to as a reinforcement learning (RL) network. In some embodiments, LDM module 108 is a type of neural network other than an RL network. LDM module 108 includes: an input layer 172; a fully connected (FC) layer 174; and an output layer 176.

In FIG. 1F, DRE module 102F receives DR-violating training features and corresponding labels, i.e., paradigmatic modifications classifications correspond to the DR-violating training features, from TDD module 160 (see FIG. 2A). DRC module 106 operates on the training features, generates corresponding inferred classifications (see FIG. 1A), and outputs the same to LDM module 108. Because the training features of FIG. 1F are DR-violating training features, all classifications output by DRC module 106 in FIG. 1F represent DR violations.

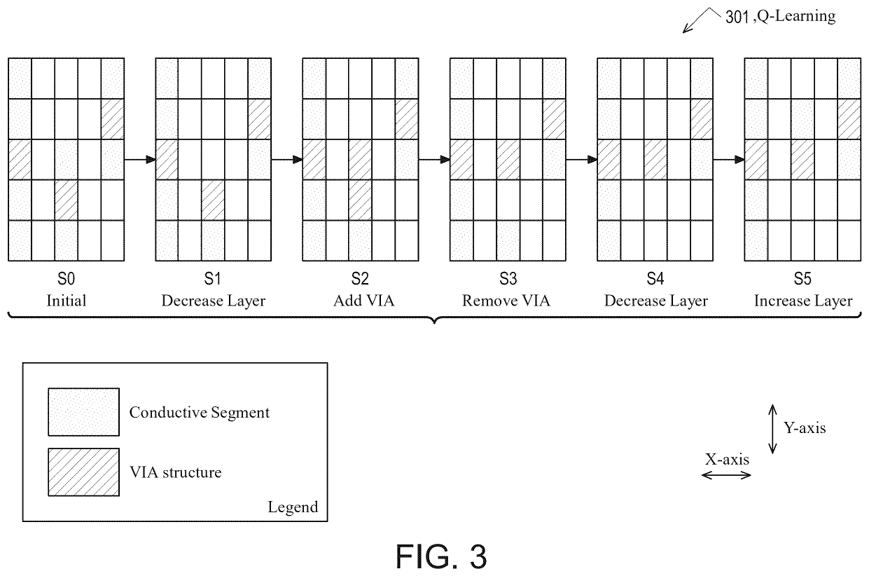

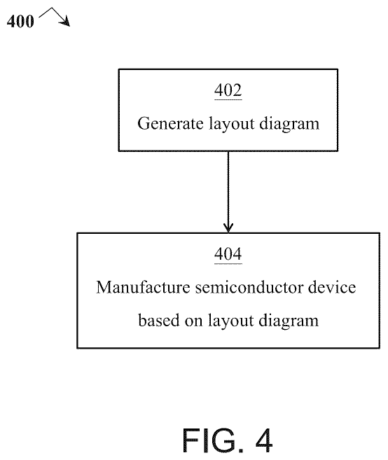

In FIG. 1F, input layer 172, FC layer 174 and output layer 176 of LDM module 108 operate on the inferred classifications similarly to how LDM module 108 operates on the inferred subject features in FIG. 1A. However, in FIG. 1F, the modifications to the DR-violating training features generated by LDM module 108 and output therefrom by output layer 176 are not provided to input layer 110(1) (FIG. 1A) of DRC module 106. Instead, the modifications output by output layer 176 are provided to an LDM-modifier module 170. Examples of the inferred modifications are discussed in the context of FIG. 3.

In addition to receiving the inferred modifications from output layer 176, LDM-modifier module 170 receives the paradigmatic modifications from TDD module 160 which correspond to the DR-violating training features. LDM-modifier module 170 adjusts one or more weights or one or more biases correspondingly of FC layer 174 by applying a recursive type of gradient descent based on differences between the paradigmatic modifications and corresponding ones of the inferred modifications. Propagation of the features from input layer 172 through FC layer 174 to output layer 176 is referred to as forward propagation 166F.

LDM-modifier module 170 adjusts weights WR(0), . . . , WR(M−1) and a bias value BR1 and provides the same to FC layer 174. In some embodiments, LDM-modifier module 170 includes one or more additional layers between input layer 172 and FC layer 174, or between FC layer 174 and output layer 176.

In some embodiments, DRC-modifier module 164 does as follows including: determines the differences according to a mean squared error between the paradigmatic modifications and the corresponding ones of the inferred modifications; and uses Adaptive Moment Estimation (Adam) as the recursive type of gradient descent.

FIG. 2A is a block diagram of a system 200A, in accordance with some embodiments.

System 200A is comprised of at least one processor, at least one non-transitory computer-readable medium (see FIG. 5) that stores computer-executable code/instructions, a library 281(1) of empirical layout diagrams and a library 281(2) of synthetic and empirical training layout diagrams, training features thereof are stored on a non-transitory computer-readable medium. In some embodiments, empirical layout diagrams are layout diagrams that have already been validated as being in DR compliance as a whole, e.g., using DR checking techniques according to other approaches. Accordingly, such empirical layout diagrams are good sources from which to extract empircal features that are in corresponding DR compliance. The non-transitory computer-readable medium also stores paradigmatic classifications (as being in DR compliance or in DR violation) corresponding to DR-compliant ones of the training features and DR-violating ones of the training features. The non-transitory computer-readable medium further stores paradigmatic modifications corresponding to the DR-violating ones of the training features. In some embodiments, system 100A is implemented using electronic design automation (EDA) system 600 of FIG. 5 (discussed below), or the like.

Regarding FIG. 2A, the non-transitory computer-readable medium, the computer-executable code and the at least one processor are configured to cause the system to generate a training-data developer (TDD) module 260A that includes at least an empirical feature extractor module 104(2), a training-data developer (TDD) module 260A, a discrim-modifier module 282, a gen-modifier module 284 and a feature consolidator module 286.

Empirical feature extractor module 104(2) is similar to subject feature extractor module 104(1) of FIG. 1A. For brevity, the discussion will focus on differences of empirical extractor module 104(2) as compared to subject extractor module 104(1). In some embodiments, empirical feature extractor module 104(2) is also configured to perform data warping on the extracted empirical features. In some embodiments, data warping includes making simple geometric transformations to the empirical features, e.g., flipping along one or two axes, cropping, resizing, translating position, rotating, or the like.

In some embodiments, empirical layout diagrams of library 281(1) are represented as corresponding sets of images, e.g., raster/bitmap images, vector images, or the like. In some embodiments, empirical layout diagrams of library 281(1) are represented in Graphic Design System (GDSII) format, which is a binary file format that represents planar geometric shapes, text labels, and related layout information in a hierarchical manner. In some embodiments, empirical layout diagrams of library 281(1) are represented in a format other than image format or GDSII format.

TDD module 260A is a neural network. FIGS. 2A-2C assume that TDD module 260A is a type of neural network referred to as a generative-adversarial network (GAN). In some embodiments, TDD module 260A is a type of neural network other than a GAN.

In FIG. 2A, TDD module 260A includes a generator module 288 and a discriminator module 290. FIGS. 2A-2C assume that each of generator module 288 and discriminator module 290 is a corresponding CNN. In some embodiments, generator module 288 and/or discriminator module 290 is/are a type of neural network other than a CNN. As each is a neural network, each of generator module 288 and discriminator module 290 learns adaptively during corresponding training modes of operation. When not in a training mode, each of generator module 288 and discriminator module 290 is described as being in a corresponding fixed mode of operation. Regarding system 200A and TDD module 260A, the suffix “A” correspondingly in the reference numbers indicates that FIG. 2A is showing the fixed mode of operation. A training mode of discriminator module 290 of TDD module 260A is discussed below in the context of FIG. 2B. A training mode of generator module 288 of TDD module 260A is discussed below in the context of FIG. 2C.

Generator module 288 is configured to receive empirical training features from empirical feature extractor 104(2). Each of generator module 288 and discrim-modifier module 282 is configured to receive corresponding labels, i.e., paradigmatic classifications corresponding to the empirical training features. Generator module 288 is also configured to output the empirical features to discriminator module 290.

Discriminator module 290 is configured to classify the empirical features, generate corresponding inferred classifications for the empirical features and provide such classifications to discrim-modifier module 282. Gen-modifier module 284 is configured to generate updated weights and biases for discriminator module 290 based on the inferred classifications for the empirical features and the corresponding labels, i.e., the corresponding paradigmatic classifications for the empirical training features.

Generator module 288 is also configured to generate/synthesize: synthetic features and output the same to discriminator module 290; and corresponding labels, i.e., paradigmatic classifications corresponding to the synthetic training features and output the same to gen-modifier module 284. Discriminator module 290 is also configured to classify the synthetic features, generate corresponding inferred classifications for the synthetic features and provide such classifications to gen-modifier module 284. Gen-modifier module 284 is configured to generate updated weights and biases for generator module 288 based on the inferred classifications for the synthetic features and the corresponding labels, i.e., the corresponding synthetic classifications for the synthetic training features.

Typically, the training mode of discriminator module 290 of TDD module 260A (see FIG. 2B) is conducted before the training mode of generator module 288 of TDD module 260A (see FIG. 2C) is conducted. In some embodiments, the training mode of generator module 288 is terminated when the rate at which (i) the inferred classifications generated by discriminator module 290 for the synthetic features match (ii) the synthetic classifications generated by generator module 290 for the synthetic features exceeds a predetermined threshold.

Feature consolidator module 286 is configured to do as follows including: receive the empirical features and corresponding labels, i.e., paradigmatic classifications corresponding to the empirical training features; receive (after the training mode of generator 288 has terminated) the synthetic features and corresponding labels, i.e., paradigmatic classifications corresponding to the synthetic empirical training features; and consolidate the various features and labels into a library 282.

FIG. 2B is a block diagram of a system 200B, in accordance with some embodiments.

System 200B and TDD module 260B included therein correspond to system 200A and TDD module 260A of FIG. 2A. Whereas FIG. 2A assumes a fixed mode of operation for TDD module 260A, FIG. 2B assumes a context of TDD module 260B being in a training mode of operation, and more particularly discriminator module 290 of TDD module 260B being in a training mode of operation. In some embodiments, the training mode of discriminator module 290 is described as supervised training. The training mode of discriminator module 290 is mutually exclusive to the training mode of generator module 288. Accordingly, FIG. 2B assumes that generator module 288 is in a fixed mode of operation.

Discriminator module 290 includes: an input layer 110(2); a deep neural network 112(2); and an output layer 114(2). Deep neural network 112(2) includes hidden layers including: Conv2D layers 118(4)-118(6); pooling layers 120(4)-120(6); FC layers 122(3)-122(4); and a dropout layer 124(2). Layers of generator module 288 are not shown in FIG. 2B, but see FIG. 2C.

In FIG. 2B, each of Conv2D layers 118(4)-118(6) is assumed to have a kernel size of 3×3. In some embodiments, one or more of Conv2D layers 118(4)-118(6) correspondingly has a kernel size different than 3×3. In FIG. 2B, each of Conv2D layers 118(4)-118(6) is assumed to have a step size of one. In some embodiments, one or more of Conv2D layers 118(4)-118(6) correspondingly has a step size different than one. In FIG. 2B, each of Conv2D layers 118(4)-118(6) is assumed to use zero padding. In some embodiments, one or more of Conv2D layers 118(4)-118(6) correspondingly uses non-zero padding.

In FIG. 2B, it is assumed that each of Conv2D layers 118(4)-118(6) has a ReLU function as an activation function. In some embodiments, one or more of Conv2D layers 118(4)-118(6) has a corresponding activation function that is different than the ReLU function.

In FIG. 2B, output layer 114(2) is assumed to have a softmax function as an activation function. In some embodiments, output layer 114(2) has an activation function that is different than the softmax function.

In FIG. 2B, pooling layers 120(4)-120(6) are assumed to be max pooling layers. In some embodiments, one or more of pooling layers 120(4)-120(6) correspondingly are different types of pooling layers than max pooling layers. In some embodiments, deep neural network 112(2) includes a different number of pooling layers than is shown in FIG. 2B. In some embodiments, deep neural network 112(2) includes a different number of Conv2D layers than is shown in FIG. 2B.

In FIG. 2B, discriminator module 290 receives empirical training features from generator module 288 which receives the same from empirical feature extractor module 104(2). Discrim-modifier module 282 receives corresponding labels, i.e., paradigmatic classifications corresponding to the empirical features, from empirical feature extractor module 104(2).

In FIG. 2B, input layer 110(2), deep neural 112(2) and output layer 114(2) of discriminator module 290 operate on the empirical features and the resultant classifications output by output layer 114(2) are provided to discrim-modifier module 282.

In addition to receiving the inferred classifications from output layer 114(2), discrim-modifier module 282 receives the paradigmatic classifications for the empirical training features, as noted above. Discrim-modifier module 282 adjusts one or more weights or one or more biases correspondingly of Conv2D layers 118(4)-118(6) by applying a recursive type of gradient descent based on differences between the paradigmatic classifications and corresponding ones of the inferred classifications. Propagation of the features from input layer 110(2) through deep neural net 112(2) to output layer 114(2) is referred to as forward propagation 266B.

Discrim-modifier module 282 adjusts weights WD1(0), . . . , WD1(M−1) and a bias value BD1 and provides the same to Conv2D layer 118(4). Discrim-modifier module 282 adjusts weights WD2(0), . . . , WD2(M−1) and a bias value BD2 and provides the same to Conv2D layer 118(5). Discrim-modifier module 282 adjusts weights WD3(0), . . . , WD3(M−1) and a bias value BD3 and provides the same to Conv2D layer 118(6). FIG. 2B assumes that each of Conv2D layers 118(4)-118(6) has M nodes/neurons. In some embodiments, one or more of Conv2D layers 118(4)-118(6) has different numbers of nodes/neurons.

In some embodiments, discrim-modifier module 282 does as follows including: determines the differences according to a categorical cross-entropy loss between the paradigmatic classifications and the corresponding ones of the inferred classifications; and uses Adaptive Moment Estimation (Adam) as the recursive type of gradient descent.

FIG. 2C is a block diagram of a system 200C, in accordance with some embodiments.

System 200C and TDD module 260C included therein correspond to system 200A and TDD module 260A of FIG. 2A. Whereas FIG. 2A assumes a fixed mode of operation for TDD module 260A, FIG. 2C assumes a context of TDD module 260C being in a training mode of operation, and more particularly generator module 288 of TDD module 260C being in a training mode of operation. In some embodiments, the training mode of generator module 288 is described as supervised training. The training mode of generator module 288 is mutually exclusive to the training mode of discriminator module 290. Accordingly, FIG. 2C assumes that discriminator module 290 is in a fixed mode of operation.

Generator module 288 includes: an input layer 110(3); a deep neural network 112(3); and an output layer 114(3). Deep neural network 112(3) includes hidden layers including: Conv2D layers 118(7)-118(9); pooling layers 120(7)-120(9); FC layers 122(5)-122(6); and a dropout layer 124(3). Layers of discriminator module 290 are not shown in FIG. 2C, but see FIG. 2B.

In FIG. 2C, each of Conv2D layers 118(7)-118(9) is assumed to have a kernel size of 3×3. In some embodiments, one or more of Conv2D layers 118(7)-118(9) correspondingly has a kernel size different than 3×3. In FIG. 2C, each of Conv2D layers 118(7)-118(9) is assumed to have a step size of one. In some embodiments, one or more of Conv2D layers 118(7)-118(9) correspondingly has a step size different than one. In FIG. 2C, each of Conv2D layers 118(7)-118(9) is assumed to use zero padding. In some embodiments, one or more of Conv2D layers 118(7)-118(9) correspondingly uses non-zero padding.

In FIG. 2C, it is assumed that each of Conv2D layers 118(7)-118(9) has a ReLU function as an activation function. In some embodiments, one or more of Conv2D layers 118(7)-118(9) has a corresponding activation function that is different than the ReLU function.

In FIG. 2C, output layer 114(3) is assumed to have a ReLU function as an activation function. In some embodiments, output layer 114(3) has an activation function that is different than the ReLU function.

In FIG. 2C, pooling layers 120(7)-120(9) are assumed to be max pooling layers. In some embodiments, one or more of pooling layers 120(7)-120(9) correspondingly are different types of pooling layers than max pooling layers. In some embodiments, deep neural network 112(3) includes a different number of pooling layers than is shown in FIG. 2C. In some embodiments, deep neural network 112(3) includes a different number of Conv2D layers than is shown in FIG. 2C.

In FIG. 2C, generator module 288 receives empirical training features from empirical feature extractor module 104(2). Generator module 288 is configured to generate/synthesize: synthetic features and output the same to discriminator module 290; and corresponding labels, i.e., paradigmatic classifications corresponding to the synthetic training features and output the same to gen-modifier module 284.

Discriminator module 290 is also configured to classify the synthetic features, generate corresponding inferred classifications for the synthetic features and provide such classifications to gen-modifier module 284. Gen-modifier module 284 is configured to generate updated weights and biases for generator module 288 based on the inferred classifications for the synthetic features and the corresponding labels, i.e., the corresponding synthetic classifications for the synthetic training features.

In FIG. 2C, input layer 110(3), deep neural 112(3) and output layer 114(3) of generator module 288 operate on the empirical training features and the corresponding labels, i.e., the corresponding paradigmatic classifications for the empirical training features.

In addition to receiving the inferred classifications from output layer 114(3), gen-modifier module 284 receives the synthetic classifications for the synthetic training features, as noted above. Gen-modifier module 284 adjusts one or more weights or one or more biases correspondingly of Conv2D layers 118(7)-118(9) by applying a recursive type of gradient descent based on differences between the synthetic classifications and corresponding ones of the inferred classifications. Propagation of the features from input layer 110(3) through deep neural net 112(3) to output layer 114(3) is referred to as forward propagation 266C.

Gen-modifier module 284 adjusts weights WG1(0), . . . , WG1(M−1) and a bias value BG1 and provides the same to Conv2D layer 118(7). Gen-modifier module 284 adjusts weights WG2(0), . . . , WG2(M−1) and a bias value BG2 and provides the same to Conv2D layer 118(8). Gen-modifier module 284 adjusts weights WG3(0), . . . , WG3(M−1) and a bias value BG3 and provides the same to Conv2D layer 118(9). FIG. 2C assumes that each of Conv2D layers 118(7)-118(9) has M nodes/neurons. In some embodiments, one or more of Conv2D layers 118(7)-118(9) has different numbers of nodes/neurons.

In some embodiments, gen-modifier module 284 does as follows including: determines the differences according to a mean squared error between the synthetic classifications and the corresponding ones of the inferred classifications; and uses Adaptive Moment Estimation (Adam) as the recursive type of gradient descent.

FIG. 3 is a flow diagram 301, in accordance with some embodiments.

FIG. 3 includes simplistic representations of features S0-S5 and corresponding inferred modifications that change a first one of the features into a second one of the features. In some embodiments, the sequence of modification is different than shown in FIG. 3.

Feature S1 represents a modification in which a conductive segment in feature S0 is randomly removed resulting in feature S1. Feature S2 represents a modification in which a via structure in feature S1 is randomly added resulting in feature S2. Feature S3 represents a modification in which a via structure in feature S2 is randomly removed resulting in feature S3. Feature S4 represents a modification in which a conductive segment in feature S3 is randomly added resulting in feature S4. Feature S5 represents a modification in which a conductive segment in feature S4 is randomly added resulting in feature S5.

In some embodiments, the learning by LDM module 108 is describes as Q-learning. In Q-learning, the state is the current configuration of the features of the layout diagram. Actions to be taken include the actions/modifications illustrated in FIG. 3. In some embodiments, an additional action is to make no modification for a given iteration. In Q-learning, the reward is the size of the mean squared error. The Q-values are parameterized Q-function Q_theta(s,a). The Q-table is updated using an FC layer in deep learning.

FIG.-4 is a flowchart (flow diagram) of a method-400 of manufacturing a system or device, in accordance with some embodiments.

Method-400 is implementable, for example, using EDA system-500 (FIG.-5, discussed below) and an IC manufacturing system-600 (FIG.-6, discussed below), in accordance with some embodiments. Examples of semiconductor devices which can be manufactured according to method-400 include the semiconductor devices based on layout diagrams generated by the systems disclosed herein, or the like.

In FIG.-4, the method of flowchart-400 includes blocks-402-704. At block-402, a layout diagram is generated which, among other things, includes one or more layout diagrams corresponding to one or more of the memories disclosed herein, or the like. Block-402 is implementable, for example, using EDA system-500 (FIG.-5, discussed below), in accordance with some embodiments. From block-402, flow proceeds to block-404.

At block-404, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system-600 in FIG.-6 below.

FIG.-5 is a block diagram of an electronic design automation (EDA) system-500, in accordance with some embodiments.

In some embodiments, EDA system-500 includes an automatic placement and routing (APR) system. In some embodiments, EDA system-500 is a general purpose computing device including a hardware processor-502 and a non-transitory, computer-readable storage medium-504. Storage medium-504, amongst other things, is encoded with, i.e., stores, computer program code-506, i.e., a set of executable instructions. Execution of instructions-506 by hardware processor-502 represents (at least in part) an EDA tool which implements a portion of or all, e.g., one or more methods or systems of generating layout diagrams disclosed herein, or the like, in accordance with one or more embodiments (hereinafter, the noted processes and/or methods).

Storage medium-504, amongst other things, stores layout diagrams-511 such as layout diagrams corresponding to the memories disclosed herein, other the like.

Processor-502 is electrically coupled to computer-readable storage medium-504 via a bus-508. Processor-502 is further electrically coupled to an I/O interface-510 by a bus-508. A network interface-512 is further electrically connected to processor-502 via bus-508. Network interface-512 is connected to a network-514, so that processor-502 and computer-readable storage medium-504 are capable of connecting to external elements via network-514. Processor-502 is configured to execute computer program code-506 encoded in computer-readable storage medium-504 in order to cause EDA system-500 to be usable for performing a portion of or all the noted processes and/or methods. In one or more embodiments, processor-502 is a central processing unit (CPU), a multi-processor, a distributed processing system, an application specific integrated circuit (ASIC), and/or a suitable processing unit.

In one or more embodiments, computer-readable storage medium-504 is an electronic, magnetic, optical, electromagnetic, infrared, and/or a semiconductor system (or apparatus or device). For example, computer-readable storage medium-504 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium-504 includes a compact disk-read only memory (CD-ROM), a compact disk-read/write (CD-R/W), and/or a digital video disc (DVD).

In one or more embodiments, storage medium-504 stores computer program code-506 configured to cause EDA system-500 (where such execution represents (at least in part) the EDA tool) to be usable for performing a portion of or all the noted processes and/or methods. In one or more embodiments, storage medium-504 further stores information which facilitates performing a portion of or all the noted processes and/or methods. In one or more embodiments, storage medium-504 stores library-507 of standard cells including standard cells that correspond to components of the memories disclosed herein. Storage medium-504 stores one or more layout diagrams-516 such as one or more layout diagrams corresponding to the memories disclosed herein, or the like.

EDA system-500 includes I/O interface-510. I/O interface-510 is coupled to external circuitry. In one or more embodiments, I/O interface-510 includes a keyboard, keypad, mouse, trackball, trackpad, touchscreen, and/or cursor direction keys for communicating information and commands to processor-502.

EDA system-500 further includes network interface-512 coupled to processor-502. Network interface-512 allows EDA system-500 to communicate with network-514, to which one or more other computer systems are connected. Network interface-512 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems-500.

EDA system-500 is configured to receive information through I/O interface-510. The information received through I/O interface-510 includes one or more of instructions, data, design rules, libraries of standard cells, and/or other parameters for processing by processor-502. The information is transferred to processor-502 via bus-508. EDA system-500 is configured to receive information related to a user interface (UI) through I/O interface-510. The information is stored in computer-readable medium-504 as UI-542.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system-500. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG.-6 is a block diagram of an integrated circuit (IC) manufacturing system-600, and an IC manufacturing flow associated therewith, in accordance with some embodiments.

In some embodiments, based on the layout diagram generated by block-402 of FIG.-4, the IC manufacturing system-600 implements block-404 of FIG.-4 wherein at least one of (A) one or more semiconductor masks or (B) at least one component in a layer of an inchoate semiconductor integrated circuit is fabricated using manufacturing system-600.

In FIG.-6, IC manufacturing system-600 includes entities, such as a design house-620, a mask house-630, and an IC manufacturer/fabricator (“fab”)-650, that interact with one another in the design, development, and manufacturing cycles and/or services related to manufacturing an IC device-660. The entities in system-600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house-620, mask house-630, and IC fab-650 is owned by a single larger company. In some embodiments, two or more of design house-620, mask house-630, and IC fab-650 coexist in a common facility and use common resources.

Design house (or design team)-620 generates an IC design layout-622. IC design layout-622 includes various geometrical patterns designed for an IC device-660. The geometrical patterns correspond to patterns of metal, oxide, or semiconductor layers that make up the various components of IC device-660 to be fabricated. The various layers combine to form various IC features. For example, a portion of IC design layout-622 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house-620 implements a proper design procedure to form IC design layout-622. The design procedure includes one or more of logic design, physical design or place and route. IC design layout-622 is presented in one or more data files having information of the geometrical patterns. For example, IC design layout-622 is expressed in a GDSII file format or DFII file format.

Mask house-630 includes data preparation-632 and mask fabrication-634. Mask house-630 uses IC design layout-622 to manufacture one or more masks-635 to be used for fabricating the various layers of IC device-660 according to IC design layout-622. Mask house-630 performs mask data preparation-632, where IC design layout-622 is translated into a representative data file (“RDF”). Mask data preparation-632 supplies the RDF to mask fabrication-634. Mask fabrication-634 includes a mask writer. A mask writer converts the RDF to an image on a substrate, such as a mask (reticle) or a semiconductor wafer. The design layout is manipulated by mask data preparation-632 to comply with particular characteristics of the mask writer and/or requirements of IC fab-650. In FIG.-6, mask data preparation-632, mask fabrication-634, and mask-635 are illustrated as separate elements. In some embodiments, mask data preparation-632 and mask fabrication-634 are collectively referred to as mask data preparation.

In some embodiments, mask data preparation-632 includes optical proximity correction (OPC) which uses lithography enhancement techniques to compensate for image errors, such as those that can arise from diffraction, interference, other process effects and the like. OPC adjusts IC design layout-622. In some embodiments, mask data preparation-632 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation-632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication-634, which may undo part of the modifications performed by OPC in order to meet mask creation rules.

In some embodiments, mask data preparation-632 includes lithography process checking (LPC) that simulates processing that will be implemented by IC fab-650 to fabricate IC device-660. LPC simulates this processing based on IC design layout-622 to fabricate a simulated manufactured device, such as IC device-660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout-622.

The above description of mask data preparation-632 has been simplified for the purposes of clarity. In some embodiments, mask data preparation-632 includes additional features such as a logic operation (LOP) to modify the IC design layout according to manufacturing rules. Additionally, the processes applied to IC design layout-622 during data preparation-632 may be executed in a variety of different orders.

After mask data preparation-632 and during mask fabrication-634, a mask-635 or a group of masks-635 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication-634 is used in a variety of processes. For example, such a mask(s) is used in an ion implantation process to form various doped regions in the semiconductor wafer, in an etching process to form various etching regions in the semiconductor wafer, and/or in other suitable processes.

IC fab-650 is an IC fabrication business that includes one or more manufacturing facilities for the fabrication of a variety of different IC products. In some embodiments, IC fab-650 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab-650 uses mask (or masks)-635 fabricated by mask house-630 to fabricate IC device-660 using fabrication tools-652. Thus, IC fab-650 at least indirectly uses IC design layout-622 to fabricate IC device-660. In some embodiments, a semiconductor wafer-653 is fabricated by IC fab-650 using mask (or masks)-635 to form IC device-660. Semiconductor wafer-653 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a system (for manufacturing a semiconductor device) includes at least one processor, at least one non-transitory computer-readable medium that stores computer-executable code, an unvalidated subject layout diagram representing the semiconductor device, the unvalidated subject layout diagram being stored on a non-transitory computer-readable medium, the non-transitory computer-readable medium, the computer-executable code and the at least one processor being configured to cause the system to generate the following including: a feature extractor module configured to extract subject features that at least partially comprise the unvalidated subject layout diagram; and a design rule (DR) enforcement module including a DR checker (DRC) module and layout diagram modifier (LDM) module, the DRC module being configured to check the subject features for compliance with corresponding design rules in a set thereof and to identify which of the design rules are being violated and corresponding DR-violating subject features, and the LDM module being configured to attempt reducing the DR violations by modifying the DR-violating subject features resulting in a validated subject layout diagram; the DRC module being based on a first neural network; and the LDM module being based on a second neural network.

In some embodiments, the first neural network of the DRC module has a first architecture; and the second neural network of the LDM module having a second architecture that is different than the first architecture.

In some embodiments, the first neural network of the DRC module is a convolution neural network (CNN) that includes: an input layer; first, second and third two-dimensional (2D) convolution layers; first, second and third pooling layers; and an output layer; the first 2D convolutional layer is between the input layer and the second 2D convolutional layer; the second 2D convolutional layer is between the first 2D convolutional layer and the third 2D convolutional layer; the third 2D convolutional layer is between the second 2D convolutional layer and the output layer; the first pooling layer is between the first 2D convolutional layer the second 2D convolutional layer; the second pooling layer is between the second 2D convolutional layer and the third 2D convolutional layer; and the third pooling layer is between the third 2D convolutional layer and the output layer.

In some embodiments, each of the first, second and third 2D convolutional layers has a kernel of size 3×3 and a stride of one; and each of the first, second and third pooling layers is configured to perform max-pooling using a corresponding 2×2 kernel.

In some embodiments, the CNN of the DRC module further includes: first and second fully connected (FC) layers; and a dropout layer; the first FC layer is between the third 2D convolutional layer and the dropout layer; the dropout layer is between the first FC layer and the second FC layer; and the second FC layer is between the dropout layer and the output layer.

In some embodiments, each of the first, second and third 2D convolutional layers has a rectified linear unit (ReLU) as an activation function; and an activation function of the output layer is a softmax function.

In some embodiments, during a fixed mode, the DR enforcement module is configured to receive the subject features of the unvalidated subject layout diagram; during a training mode, the DR enforcement module is configured to receive training features of one or more training layout diagrams and labels corresponding to the training features, the labels representing paradigmatic classifications of the training features correspondingly as being a design rule (DR) compliance or as being a DR violation; during the fixed mode or during the training mode, the output layer is configured to generate inferred classifications by classifying the subject features or the training features correspondingly as being in design rule (DR) compliance or as being in DR violation; the DR enforcement module further includes a DRC-modifier module which is operative during the training mode; and during the training mode, the DRC-modifier module is configured to adjust one or more weights or one or more biases correspondingly of the first, second and third 2D convolutional layers by applying a recursive type of gradient descent based on differences between the paradigmatic classifications and corresponding ones of the inferred classifications.

In some embodiments, during the training mode, the DRC-modifier module is further configured to determine the differences according to categorical cross-entropy loss between the paradigmatic classifications and the corresponding ones of the inferred classifications; and during the training mode, the recursive type of gradient descent is Adaptive Moment Estimation (Adam).

In some embodiments, the second neural network of the DRC module is a reinforcement learning (RL) network that includes: an input layer; a fully connected (FC) layer couple to the input layer; an output layer coupled to the FC layer.

In some embodiments, during a fixed mode, the DR enforcement module is configured to receive the subject features of the unvalidated subject layout diagram; during a training mode, the DR enforcement module is configured to receive training features of one or more training layout diagrams and labels corresponding to the training features, each of the training features being in DR violation, and the labels representing paradigmatic modifications to the training features that would result in the training features being in design rule (DR) compliances; during the fixed mode or during the training mode, the output layer is configured to generate inferred modifications intended to modify correspondingly the training features to be in corresponding DR compliance; the DR enforcement module further includes an LDM-modifier module which is operative during the training mode; and during the training mode, the LDM-modifier module is configured to adjust one or more weights or one or more biases of the FC layer by applying a recursive type of gradient descent based on differences between the paradigmatic modifications and corresponding ones of the inferred modifications.

In some embodiments, during the training mode, the LDM-modifier module is further configured to determine the differences according to a mean squared error between the paradigmatic modifications and the corresponding ones of the inferred modifications; and during the training mode, the recursive type of gradient descent is Adaptive Moment Estimation (Adam).

In some embodiments, the system further includes at least one of: a masking facility configured to fabricate one or more semiconductor masks based on the validated subject layout diagram; or a fabricating facility configured to fabricate at least one component in a layer of a semiconductor integrated circuit based on the validated subject layout diagram.

In some embodiments, a system (for manufacturing a semiconductor device) includes at least one processor; at least one non-transitory computer-readable medium that stores computer-executable code; one or more empirical training layout diagrams of one or more corresponding empirical semiconductor devices, the one or more empirical training layout diagrams stored on a non-transitory computer-readable medium, the non-transitory computer-readable medium, the computer-executable code and the at least one processor being configured to cause the system to generate the following including: a training data-developer (TDD) module including an empirical feature extractor module and a feature synthesizer module; the empirical feature extractor module being configured to extract empirical training features that at least partially comprise one or more corresponding empirical training layout diagrams and that are in design rule (DR) compliance with corresponding design rules; the feature synthesizer module being based on a first neural network and being configured to generate first synthetic training features useable in one or more corresponding training layout diagrams and that are in compliance with corresponding design rules or second synthetic training features useable in one or more corresponding training layout diagrams and that are in violation of corresponding design rules.

In some embodiments, the first neural network of the feature synthesizer module is a generative-adversarial network (GAN) that includes a generator module and a discriminator module cooperatively coupled to each other; the generator module includes a first convolution neural network (CNN); and the discriminator module includes a second CNN that is different than the first CNN.

In some embodiments, each of the first CNN and the second CNN includes: an input layer; first, second and third two-dimensional (2D) convolution layers; first, second and third pooling layers; and an output layer; each of the first 2D convolutional layers is between the corresponding input layer and the corresponding second 2D convolutional layer; each of the second 2D convolutional layers is between the corresponding first 2D convolutional layer and the corresponding third 2D convolutional layer; each of the third 2D convolutional layers is between the corresponding second 2D convolutional layer and the corresponding output layer; each of the first pooling layers is between the corresponding first 2D convolutional layer the corresponding second 2D convolutional layer; each of the second pooling layers is between the corresponding second 2D convolutional layer and the corresponding third 2D convolutional layer; and each of the third pooling layers is between the corresponding third 2D convolutional layer and the corresponding output layer.

In some embodiments, each of the first, second and third pooling layers is configured to perform max-pooling using a corresponding 2×2 kernel.

In some embodiments, each of the first CNN and the second CNN includes: first and second fully connected (FC) layers; and a dropout layer; each of the first FC layers is between the corresponding third 2D convolutional layer and the corresponding dropout layer; each of the dropout layers is between the corresponding first FC layer and the corresponding second FC layer; and each of the second FC layers is between the corresponding dropout layer and the corresponding output layer.

In some embodiments, for each of the first CNN and the second CNN, each of the corresponding first, second and third 2D convolutional layers has a kernel of size 3×3 and a stride of one.

In some embodiments, for each of the first CNN and the second CNN, each of the first, second and third 2D convolutional layers has a rectified linear unit (ReLU) function as an activation function.

In some embodiments, the first neural network of the feature synthesizer module is a generative-adversarial network (GAN) that includes a generator module and a discriminator module cooperatively coupled to each other; the generator module includes a first convolution neural network (CNN); the discriminator module includes a second CNN that is different than the first CNN; for the first CNN of the generator module, an activation function of the output layer is a rectified linear unit (ReLU) function; and for the second CNN of the discriminator module, an activation function of the output layer is a softmax function.

In some embodiments, the first neural network of the feature synthesizer module is a generative-adversarial network (GAN) that includes a generator module and a discriminator module cooperatively coupled to each other; the generator module includes a first convolution neural network (CNN); the discriminator module includes a second CNN that is different than the first CNN; during a generation-training mode of the first CNN of the generator module, the second CNN of the discriminator module is configured to operate in a fixed mode; during the generation-training mode, the first CNN is configured to receive one or more of the empirical training features from the empirical feature extractor module, correspondingly generate one or more first faux training features or one or more second faux training features and provide the same to the second CNN of the discriminator module, the one or more first faux training features having corresponding expected classifications as being in DR compliance; the one or more second faux training features having corresponding expected classifications as being in DR violation; during the generation-training mode, the output layer of the second CNN of the discriminator module is configured to generate inferred classifications by classifying the one or more faux training features or the one or more second faux training features correspondingly as being in DR compliance or as being in DR violation; the TDD module further includes a gen-modifier module which is operative during the training mode of the first CNN; and during the generation-training mode, the gen-modifier module is configured to adjust one or more weights or one or more biases correspondingly of the first, second and third 2D convolutional layers of the first CNN by applying a recursive type of gradient descent based on differences between the expected classifications and corresponding ones of the inferred classifications.

In some embodiments, during the generation-training mode, the gen-modifier module is further configured to determine the differences according to a mean squared error between the expected classifications and the corresponding ones of the inferred classifications; and during the generation-training mode, the recursive type of gradient descent is Adaptive Moment Estimation (Adam).

In some embodiments, the first neural network of the feature synthesizer module is a generative-adversarial network (GAN) that includes a generator module and a discriminator module cooperatively coupled to each other; the generator module includes a first convolution neural network (CNN); the discriminator module includes a second CNN that is different than the first CNN; during a discrimination-training mode of the second CNN of the discriminator module, the first CNN of the generator module is configured to operate in a fixed mode; during the discrimination-training mode, the second CNN is configured to receive one or more of the empirical training features and labels corresponding to the empirical training features from the generator module, each of the empirical training features being in DR compliance or DR violation, and the labels representing corresponding paradigmatic classifications of the empirical training features being in DR compliance or DR violation; during the discrimination-training mode, the output layer of the second CNN of the discriminator module is configured to generate inferred classifications by classifying the one or more empirical training features from the generator module correspondingly as being in DR compliance or as being in DR violation; the TDD module further includes a discrim-modifier module which is operative during the discrimination-training mode; and during the discrimination-training mode, the discrim-modifier module is configured to adjust one or more weights or one or more biases of the first, second and third 2D convolutional layers of the second CNN by applying a recursive type of gradient descent based on differences between the paradigmatic classifications and corresponding ones of the inferred classifications.

In some embodiments, during the discrimination-training mode, the discrim-modifier module is further configured to determine the differences according to categorical cross-entropy loss between the paradigmatic classifications and the corresponding ones of the inferred classifications; and during the discrimination-training mode, the recursive type of gradient descent is Adaptive Moment Estimation (Adam).

In some embodiments, the system further includes at least one of: a masking facility configured to fabricate one or more semiconductor masks based on the a validated version of an unvalidated subject layout diagram that was validated by a design rule (DR) enforcement module trained according to the empirical training features or the first or second synthetic training features of the TDD module; or a fabricating facility configured to fabricate at least one component in a layer of a semiconductor integrated circuit based on the validated subject layout diagram.

In some embodiments, the TDD module further includes: a feature consolidator module configured to consolidate the empirical training features and the first or second synthetic training features and provide a same to a design rule (DR) enforcement module.

In some embodiments, as system (for manufacturing a semiconductor device) includes: at least one processor; at least one non-transitory computer-readable medium that stores computer-executable code; an unvalidated subject layout diagram representing the semiconductor device and one or more empirical training layout diagrams of one or more corresponding empirical semiconductor devices, the unvalidated subject layout diagram and the one or more empirical training layout diagrams of one or more corresponding empirical semiconductor devices being stored on a non-transitory computer-readable medium, the non-transitory computer-readable medium, the computer-executable code and the at least one processor being configured to cause the system to generate the following including: a training data-developer (TDD) module including an empirical feature extractor module and a feature synthesizer module; the empirical feature extractor module being configured to extract empirical training features that at least partially comprise one or more corresponding empirical training layout diagrams and that are in design rule (DR) compliance with corresponding design rules; the feature synthesizer module being based on a first neural network and being configured to generate first synthetic training features useable in one or more corresponding training layout diagrams and that are in compliance with corresponding design rules or second synthetic training features useable in one or more corresponding training layout diagrams and that are in violation of corresponding design rules; a subject feature extractor module configured to extract subject features that at least partially comprise the unvalidated subject layout diagram; and a design rule (DR) enforcement module including a DR checker (DRC) module and layout diagram modifier (LDM) module each of which having been trained according to the empirical training features or the first or second synthetic training features of the TDD module, the DRC module being configured to check the subject features for compliance with corresponding design rules in a set thereof and to identify which of the design rules are being violated and corresponding DR-violating subject features, and the LDM module being configured to attempt reducing the DR violations by modifying the DR-violating subject features resulting in a validated subject layout diagram; and the DRC module being based on a third neural network or the LDM module being based on a fourth neural network.

In some embodiments, the first neural network of the feature synthesizer module is a generative-adversarial network (GAN) that includes a generator module and a discriminator module cooperatively coupled to each other; the generator module includes a first convolution neural network (CNN); the discriminator module includes a second CNN that is different than the first CNN; and the third neural network of the DRC module is a third (CNN) or the fourth neural network of the LDM module is a reinforcement learning (RL) network.

In some embodiments, the TDD module further includes: a feature consolidator module configured to consolidate the empirical training features and the first or second synthetic training features and provide a same to the design rule (DR) enforcement module.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A system for manufacturing a semiconductor device, the system comprising:
at least one processor;
at least one non-transitory computer-readable medium that stores computer-executable code;
an unvalidated subject layout diagram representing the semiconductor device, the unvalidated subject layout diagram being stored on a non-transitory computer-readable medium,
the non-transitory computer-readable medium, the computer-executable code and the at least one processor being configured to cause the system to generate the following including:
a feature extractor module configured to extract subject features that at least partially comprise the unvalidated subject layout diagram; and
a design rule (DR) enforcement module including a DR checker (DRC) module and layout diagram modifier (LDM) module,
the DRC module being configured to check the subject features for compliance with corresponding design rules in a set thereof and to identify which of the design rules are being violated and corresponding DR-violating subject features, and
the LDM module being configured to attempt reducing the DR violations by modifying the DR-violating subject features resulting in a validated subject layout diagram;
the DRC module being based on a first neural network; and
the LDM module being based on a second neural network.

2. The system of claim 1, wherein:
the first neural network of the DRC module is a convolution neural network (CNN) that includes:
an input layer;
first, second and third two-dimensional (2D) convolution layers;
first, second and third pooling layers; and
an output layer;
the first 2D convolutional layer is between the input layer and the second 2D convolutional layer;
the second 2D convolutional layer is between the first 2D convolutional layer and the third 2D convolutional layer;
the third 2D convolutional layer is between the second 2D convolutional layer and the output layer;
the first pooling layer is between the first 2D convolutional layer the second 2D convolutional layer;
the second pooling layer is between the second 2D convolutional layer and the third 2D convolutional layer; and
the third pooling layer is between the third 2D convolutional layer and the output layer.

3. The system of claim 2, wherein:
each of the first, second and third 2D convolutional layers has a kernel of size 3×3 and a stride of one; and
each of the first, second and third pooling layers is configured to perform max-pooling using a corresponding 2×2 kernel.

4. The system of claim 2, wherein:
the CNN of the DRC module further includes:
first and second fully connected (FC) layers; and
a dropout layer;
the first FC layer is between the third 2D convolutional layer and the dropout layer;
the dropout layer is between the first FC layer and the second FC layer; and
the second FC layer is between the dropout layer and the output layer.

5. The system of claim 2, wherein:
during a fixed mode, the DR enforcement module is configured to receive the subject features of the unvalidated subject layout diagram;
during a training mode, the DR enforcement module is configured to receive training features of one or more training layout diagrams and labels corresponding to the training features, the labels representing paradigmatic classifications of the training features correspondingly as being a design rule (DR) compliance or as being a DR violation;
during the fixed mode or during the training mode, the output layer is configured to generate inferred classifications by classifying the subject features or the training features correspondingly as being in design rule (DR) compliance or as being in DR violation;
the DR enforcement module further includes a DRC-modifier module which is operative during the training mode; and
during the training mode, the DRC-modifier module is configured to adjust one or more weights or one or more biases correspondingly of the first, second and third 2D convolutional layers by applying a recursive type of gradient descent based on differences between the paradigmatic classifications and corresponding ones of the inferred classifications.

6. The system of claim 5, wherein:
during the training mode, the DRC-modifier module is further configured to determine the differences according to categorical cross-entropy loss between the paradigmatic classifications and the corresponding ones of the inferred classifications; and
during the training mode, the recursive type of gradient descent is Adaptive Moment Estimation (Adam).

7. The system of claim 1, wherein:
the second neural network of the DRC module is a reinforcement learning (RL) network that includes:
an input layer;
a fully connected (FC) layer couple to the input layer;
an output layer coupled to the FC layer.

8. The system of claim 7, wherein:
during a fixed mode, the DR enforcement module is configured to receive the subject features of the unvalidated subject layout diagram;
during a training mode, the DR enforcement module is configured to receive training features of one or more training layout diagrams and labels corresponding to the training features, each of the training features being in DR violation, and the labels representing paradigmatic modifications to the training features that would result in the training features being in design rule (DR) compliances;
during the fixed mode or during the training mode, the output layer is configured to generate inferred modifications intended to modify correspondingly the training features to be in corresponding DR compliance;
the DR enforcement module further includes an LDM-modifier module which is operative during the training mode; and
during the training mode, the LDM-modifier module is configured to adjust one or more weights or one or more biases of the FC layer by applying a recursive type of gradient descent based on differences between the paradigmatic modifications and corresponding ones of the inferred modifications.

9. The system of claim 8, wherein:
during the training mode, the LDM-modifier module is further configured to determine the differences according to a mean squared error between the paradigmatic modifications and the corresponding ones of the inferred modifications; and
during the training mode, the recursive type of gradient descent is Adaptive Moment Estimation (Adam).

10. The system of claim 1, further comprising at least one of:
a masking facility configured to fabricate one or more semiconductor masks based on the validated subject layout diagram; or
a fabricating facility configured to fabricate at least one component in a layer of a semiconductor integrated circuit based on the validated subject layout diagram.

11. A system for manufacturing a semiconductor device, the system comprising:
at least one processor;
at least one non-transitory computer-readable medium that stores computer-executable code;
one or more empirical training layout diagrams of one or more corresponding empirical semiconductor devices, the one or more empirical training layout diagrams stored on a non-transitory computer-readable medium,
the non-transitory computer-readable medium, the computer-executable code and the at least one processor being configured to cause the system to generate the following including:
a training data-developer (TDD) module including an empirical feature extractor module and a feature synthesizer module;
the empirical feature extractor module being configured to extract empirical training features that at least partially comprise one or more corresponding empirical training layout diagrams and that are in design rule (DR) compliance with corresponding design rules;
the feature synthesizer module being based on a first neural network and being configured to generate first synthetic training features useable in one or more corresponding training layout diagrams and that are in compliance with corresponding design rules or second synthetic training features useable in one or more corresponding training layout diagrams and that are in violation of corresponding design rules.

12. The system of claim 11, wherein:
the first neural network of the feature synthesizer module is a generative-adversarial network (GAN) that includes a generator module and a discriminator module cooperatively coupled to each other;
the generator module includes a first convolution neural network (CNN); and
the discriminator module includes a second CNN that is different than the first CNN.

13. The system of claim 12, wherein:
the first neural network of the feature synthesizer module is a generative-adversarial network (GAN) that includes a generator module and a discriminator module cooperatively coupled to each other;
the generator module includes a first convolution neural network (CNN);
the discriminator module includes a second CNN that is different than the first CNN;
for the first CNN of the generator module,
an activation function of the output layer is a rectified linear unit (ReLU) function; and
for the second CNN of the discriminator module,
an activation function of the output layer is a softmax function.

14. The system of claim 12, wherein:
the first neural network of the feature synthesizer module is a generative-adversarial network (GAN) that includes a generator module and a discriminator module cooperatively coupled to each other;
the generator module includes a first convolution neural network (CNN);
the discriminator module includes a second CNN that is different than the first CNN;
during a generation-training mode of the first CNN of the generator module, the second CNN of the discriminator module is configured to operate in a fixed mode;
during the generation-training mode, the first CNN is configured to receive one or more of the empirical training features from the empirical feature extractor module, correspondingly generate one or more first faux training features or one or more second faux training features and provide the same to the second CNN of the discriminator module,
the one or more first faux training features having corresponding expected classifications as being in DR compliance;
the one or more second faux training features having corresponding expected classifications as being in DR violation;
during the generation-training mode, the output layer of the second CNN of the discriminator module is configured to generate inferred classifications by classifying the one or more faux training features or the one or more second faux training features correspondingly as being in DR compliance or as being in DR violation;
the TDD module further includes a gen-modifier module which is operative during the training mode of the first CNN; and
during the generation-training mode, the gen-modifier module is configured to adjust one or more weights or one or more biases correspondingly of the first, second and third 2D convolutional layers of the first CNN by applying a recursive type of gradient descent based on differences between the expected classifications and corresponding ones of the inferred classifications.

15. The system of claim 14, wherein:
during the generation-training mode, the gen-modifier module is further configured to determine the differences according to a mean squared error between the expected classifications and the corresponding ones of the inferred classifications; and
during the generation-training mode, the recursive type of gradient descent is Adaptive Moment Estimation (Adam).

16. The system of claim 12, wherein:
the first neural network of the feature synthesizer module is a generative-adversarial network (GAN) that includes a generator module and a discriminator module cooperatively coupled to each other;
the generator module includes a first convolution neural network (CNN);
the discriminator module includes a second CNN that is different than the first CNN;
during a discrimination-training mode of the second CNN of the discriminator module, the first CNN of the generator module is configured to operate in a fixed mode;
during the discrimination-training mode, the second CNN is configured to receive one or more of the empirical training features and labels corresponding to the empirical training features from the generator module,
each of the empirical training features being in DR compliance or DR violation, and the labels representing corresponding paradigmatic classifications of the empirical training features being in DR compliance or DR violation;
during the discrimination-training mode, the output layer of the second CNN of the discriminator module is configured to generate inferred classifications by classifying the one or more empirical training features from the generator module correspondingly as being in DR compliance or as being in DR violation;
the TDD module further includes a discrim-modifier module which is operative during the discrimination-training mode; and
during the discrimination-training mode, the discrim-modifier module is configured to adjust one or more weights or one or more biases of the first, second and third 2D convolutional layers of the second CNN by applying a recursive type of gradient descent based on differences between the paradigmatic classifications and corresponding ones of the inferred classifications.

17. The system of claim 16, wherein:
during the discrimination-training mode, the discrim-modifier module is further configured to determine the differences according to categorical cross-entropy loss between the paradigmatic classifications and the corresponding ones of the inferred classifications; and
during the discrimination-training mode, the recursive type of gradient descent is Adaptive Moment Estimation (Adam).

18. The system of claim 11, further comprising at least one of:
a masking facility configured to fabricate one or more semiconductor masks based on the a validated version of an unvalidated subject layout diagram that was validated by a design rule (DR) enforcement module trained according to the empirical training features or the first or second synthetic training features of the TDD module; or
a fabricating facility configured to fabricate at least one component in a layer of a semiconductor integrated circuit based on the validated subject layout diagram.

19. A system for manufacturing a semiconductor device, the system comprising:
at least one processor;
at least one non-transitory computer-readable medium that stores computer-executable code;
an unvalidated subject layout diagram representing the semiconductor device and one or more empirical training layout diagrams of one or more corresponding empirical semiconductor devices, the unvalidated subject layout diagram and the one or more empirical training layout diagrams of one or more corresponding empirical semiconductor devices being stored on a non-transitory computer-readable medium,
the non-transitory computer-readable medium, the computer-executable code and the at least one processor being configured to cause the system to generate the following including:
a training data-developer (TDD) module including an empirical feature extractor module and a feature synthesizer module;
the empirical feature extractor module being configured to extract empirical training features that at least partially comprise one or more corresponding empirical training layout diagrams and that are in design rule (DR) compliance with corresponding design rules;
the feature synthesizer module being based on a first neural network and being configured to generate first synthetic training features useable in one or more corresponding training layout diagrams and that are in compliance with corresponding design rules or second synthetic training features useable in one or more corresponding training layout diagrams and that are in violation of corresponding design rules;
a subject feature extractor module configured to extract subject features that at least partially comprise the unvalidated subject layout diagram; and
a design rule (DR) enforcement module including a DR checker (DRC) module and layout diagram modifier (LDM) module each of which having been trained according to the empirical training features or the first or second synthetic training features of the TDD module,
the DRC module being configured to check the subject features for compliance with corresponding design rules in a set thereof and to identify which of the design rules are being violated and corresponding DR-violating subject features, and
the LDM module being configured to attempt reducing the DR violations by modifying the DR-violating subject features resulting in a validated subject layout diagram; and
the DRC module being based on a third neural network or the LDM module being based on a fourth neural network.

20. The system of claim 19, wherein:
the first neural network of the feature synthesizer module is a generative-adversarial network (GAN) that includes a generator module and a discriminator module cooperatively coupled to each other;
the generator module includes a first convolution neural network (CNN);
the discriminator module includes a second CNN that is different than the first CNN; and
the third neural network of the DRC module is a third (CNN) or the fourth neural network of the LDM module is a reinforcement learning (RL) network.
